(19) United States
(12) Patent Application Publication
(10) Pub. No.: US 2017/0252785 A1
(43) Pub. Date: Sep. 7, 2017

(54) IN-SITU EUV COLLECTOR CLEANING UTILIZING A CRYOGENIC PROCESS

(71) Applicant: GLOBALFOUNDRIES Inc., Grand Cayman (KY)

(72) Inventor: Erik Robert HOSLER, Cohoes, NY (US)

(21) Appl. No.: 15/062,257

(22) Filed: Mar. 7, 2016

(51) Int. Cl. B08B 13/00; G03F 7/20

(52) U.S. Cl. CPC B08B 13/00; G03F 7/70925

(57) ABSTRACT

Method and apparatus for in-situ EUV collector cleaning utilizing a cryogenic process and a magnetic trap are disclosed. Embodiments include providing a light source collector including a reflective surface; applying a cooling agent to a surface of the collector for accelerating transformations of characteristics of contaminants on the reflective surface; applying a purging agent to the reflective surface for dislodging the transformed contaminants; and removing the dislodged contaminants to a collection pod remote from the reflective surface.

### TECHNICAL FIELD

The present disclosure relates generally to designing and fabricating integrated circuit (IC) devices. The present disclosure is particularly applicable to cryogenic processes for in-situ EUV collector cleaning in a semiconductor fabrication facility.

### BACKGROUND

A photolithography (lithography) process may be used in the fabrication of semiconductor devices where a light beam may be utilized to print/reproduce patterns (e.g. through photomasks) of various elements of a circuit design on surfaces of different layers of a silicon (Si) substrate. Through various fabrication steps, the reproduced/printed patterns may be further processed (e.g. etched) to create devices (e.g. transistors) and circuits forming an IC device. With advancements in IC design and fabrication technologies, the patterns may be printed in smaller scales for producing smaller and more efficient IC devices. A light source with a smaller wavelength, such as an extreme-ultraviolet (EUV) light/beam (e.g. with 13.5 nm wavelength photons), may be utilized to achieve a better resolution when compared to other light source options (e.g. excimer light source at 193 nm).

FIG. 1A illustrates a collector 101 of a lithography apparatus (not shown for illustrative convenience) utilized in a lithography process, wherein EUV light may be generated by a laser (e.g. a carbon-dioxide (CO₂) based laser) produced plasma (LPP) process. Through an opening 103 in the collector 101, a high energy laser beam 105 is directed at a target material 107 (for example, a tin (Sn) droplet with a diameter of less than 100 μm), provided by a droplet generator 109, travelling in vacuum across a path of the laser beam 105. Illumination of the droplet 107 by the laser beam 105 produces a hot dense plasma layer on the droplet 107 that excites the remaining portion of the droplet 107, emitting photons necessary for generating EUV light. The photons are then collected by the collector 101 and reflected by its reflective surface 111 to a series of reflectors/mirrors (not shown for illustrative convenience), which direct the EUV light for use in the lithography process. As illustrated in FIG. 1B, some contaminants including droplet fragments 113 as well as isotropic deposition of ions, electrons, and other particles 115, produced during the plasma generation and excitation of the droplet, may be deposited on the reflective surface 111. Accumulated contaminants can progressively affect the reflective characteristics of the reflective surface 111 by covering/blocking portions of it as well as eroding materials thereon.

Current processes for addressing contaminants on a collector of a lithography apparatus may require replacing the collector after some period of use. Alternatively, a collector may be taken offline for cleaning of an isotropic deposition; however, the collector would have to be removed so trained technicians may clean/remove droplet fragments, which may continue to grow in size over time if not removed. Either option can be costly and require down-time for the lithography apparatus impacting the financial resources and productivity targets of a semiconductor manufacturer utilizing such a lithography process/apparatus. Other processes may utilize cleaning agents (e.g. chemicals/etchants) that can further erode the material on the reflective surface.

Therefore, a need exists for methodology enabling efficient and safe cleaning for a collector in a lithography apparatus.

### SUMMARY

An aspect of the present disclosure is a method for in-situ EUV collector cleaning utilizing a cryogenic process and a magnetic trap.

Another aspect of the present disclosure is an apparatus utilized for in-situ EUV collector cleaning utilizing a cryogenic process and a magnetic trap.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure some technical effects may be achieved in part by a method including providing a light source collector including a reflective surface; applying a cooling agent to a surface of the collector for accelerating transformations of characteristics of contaminants on the reflective surface; applying a purging agent to the reflective surface for dislodging the transformed contaminants; and removing the dislodged contaminants to a collection pod remote from the reflective surface.

One aspect includes coupling a cryogenic cooling chamber to the collector for the application of the cooling agent.

Another aspect includes coupling a purging chamber to an upper perimeter of the collector for the application of the purging agent; and removing the dislodged contaminants to a center point at an upper surface of the collector for guiding the dislodged contaminants to the collection pod.

A further aspect includes applying a magnetic field to the center point at a lower surface of the collector for guiding the dislodged contaminants to the collection pod.

In one aspect, the transformed characteristics of the contaminants include a diamagnetic, semiconductor brittle state.

In another aspect, the contaminants include isotropic deposition and drip-on particles from a plasma material formed in generation of an extreme-ultraviolet beam.

In an additional aspect, the contaminants are from tin in a plasma state.

Another aspect includes cooling the surface of the collector to a temperature less than negative 20 degrees Celsius (° C.).

In one aspect, the light source collector is in a normal operating mode.

Another aspect of the present disclosure is an apparatus including: a light source collector including a reflective surface; a cryogenic cooling chamber, including a cooling agent, coupled to the collector to accelerate transformations of characteristics of contaminants on the reflective surface; a purging chamber, including a purging agent, coupled to an upper perimeter of the collector to apply the purging agent to dislodge the transformed contaminants; and a collection pod remote from the reflective surface to collect the dislodged contaminants.

In one aspect, the dislodged contaminants are guided to the collection pod through a channel at a center point of an upper surface of the collector.

One aspect includes a magnetic field applied to the center point of a lower surface of the collector to guide the dislodged contaminants to the collection pod.

In another aspect the transformed characteristics of the contaminants include a diamagnetic, semiconductor brittle state.

In a further aspect the contaminants include isotropic deposition and drip-on particles from a plasma material formed in generation of an extreme-ultraviolet beam.

In an additional aspect the contaminants are from tin in a plasma state.

In one aspect, the surface of the collector is cooled to a temperature less than negative 20° C.

In another aspect, the light source collector is in a normal operating mode.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B illustrate example diagrams of a collector in a lithography apparatus; and

FIGS. 2A through 2D illustrate a process of using a collector in a lithography apparatus including a cryogenic component, in accordance with an exemplary embodiment.

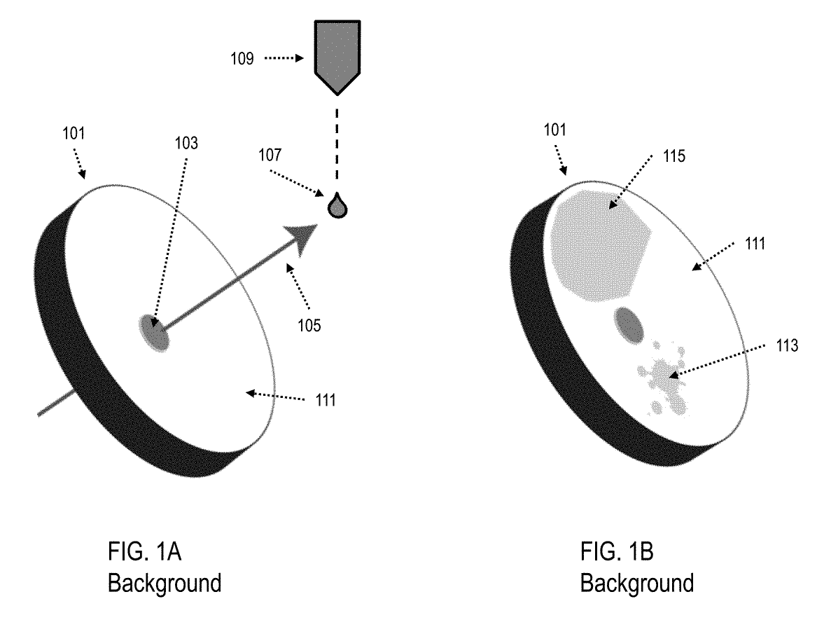

### DETAILED DESCRIPTION

For the purposes of clarity, in the following description, numerous specific details are set forth to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problems of required down-time and removal of the collector attendant upon cleaning contaminants from a reflective surface of an EUV collector in a lithography apparatus. The present disclosure addresses and solves such problems, for instance, by, inter alia, utilizing a cryogenic process and a magnetic trap in-situ for EUV collector cleaning.

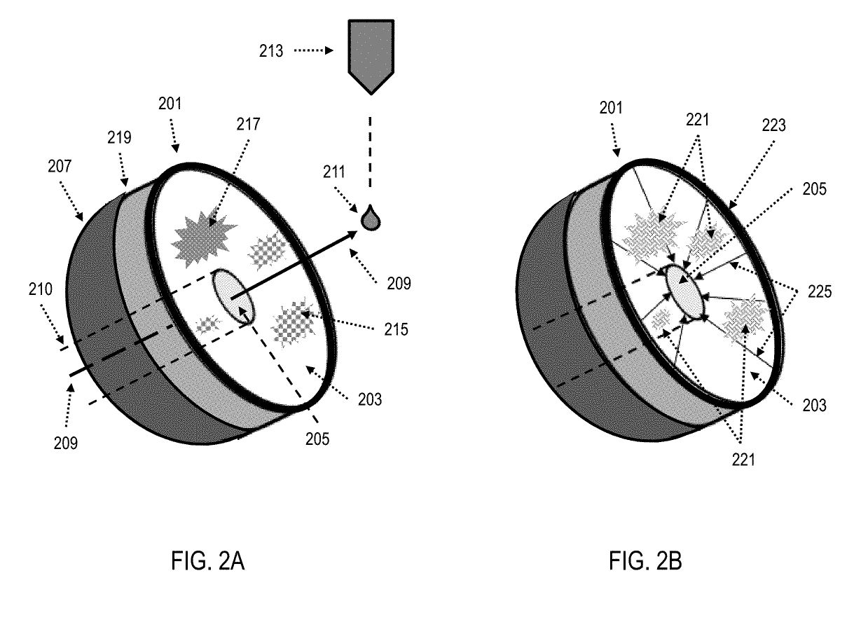

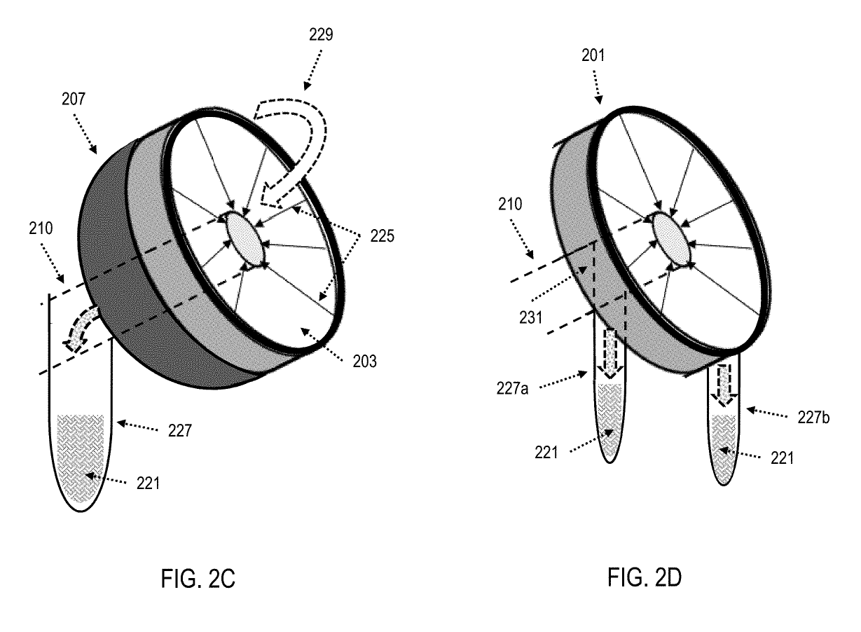

FIG. 2A illustrates a light source collector 201 including a reflective surface 203 with an opening 205 at or near the center of the reflective surface 203. A cryogenic cooling chamber 207, including a cooling agent (e.g. liquid or gas), is coupled to the collector 201. A high energy light beam 209 (e.g. laser) is guided through a channel 210 that extends through the cooling chamber 207 and the collector 201 to the opening 205. The high energy light beam 209 is directed on a collision path to a droplet 211 of a material (e.g., Sn, xenon (Xe), etc.), provided by a droplet generator 213, that may be used in generating EUV light. As noted earlier, illumination of the droplet 211 by the laser beam 209 produces a hot dense plasma layer on the droplet 211, which excites the remaining portion of the droplet 211 emitting photons necessary for generating the EUV light. During the plasma generation and vaporization of the droplet 211, contaminants including droplet fragments 215 and an isotropic deposition layer 217 including ions, electrons, and other particles may be produced and deposited on the reflective surface 203.

The cooling agent (e.g., nitrogen, oxygen, etc.) may be applied, for example, through a circulating network of channels, to a surface 219 between the collector 201 and the cooling chamber 207 or to a lower surface (not shown for illustrative convenience) of the reflective surface 203. The collector 201 and/or the reflective surface 203 may be cooled to a lower temperature, for example, based on properties of a target material used in the EUV light generation process. The cooling process can accelerate a transformation of one or more characteristics of the contaminants 215 and 217 on the reflective surface 203. For instance, Sn begins to convert from a paramagnetic, metallic and ductile β-state to the diamagnetic, semiconductor and brittle α-state at 13.2° C., but this process may be accelerated at a temperature below −20° C.

Adverting to FIG. 2B, due to the cooling process, the transformed contaminants 221 (e.g. Sn) are in a diamagnetic, semiconductor brittle state. A purging chamber 223, including a purging agent 225 (e.g. an inert gas), may be coupled to an upper perimeter of the collector 201 to apply the purging agent 225 to the reflective surface 203 to dislodge the transformed contaminants 221. Additionally, cooling the collector 201 will further enable source power scaling to prevent warping of the collector as both EUV and laser beam powers may be increased to meet requirements of high volume manufacturing levels (e.g. +250 Watts). In some instances, the cooling chamber 207 may apply the cooling agent through shared or different channels that may be available in the purging chamber 223. For example, an application of a cooling agent may be followed by an application of a purging agent through the same or different openings along the purging chamber 223.

FIG. 2C illustrates a collection pod 227 that may be placed, remote from the reflective surface 203, interfacing with the channel 210 at a lower surface of the cooling chamber 207, for collecting the dislodged contaminants 221. The contaminants 221 may be directed/guided to the collection pod 227 by a continuous application of the purging agent 225. In addition to or instead of directing the contaminants 221 by application of the purging agent 225, a magnetic field 229 may be applied to a center point of a lower surface of the collector (e.g. through the channel 210) to guide the dislodged contaminants to the collection pod 227. The magnetic field 229 may be generated by or in conjunction with a magnetic collection pod 227.

As illustrated in FIG. 2D, a collection pod 227a be placed, remote from the reflective surface 203, to interface with another channel 231 at a lower surface of the collector 201 (e.g. between the collector 201 and the cooling chamber 207) interfacing with the channel 210. Also as illustrated, a collection pod 227b may be placed, near the reflective surface 203, such that the contaminants 221 travel not through the channel 210 but, for example, through an opening along the perimeter of the collector 201.

It is noted that above discussed processes may be performed while the light source collector 201 is in a normal operating mode and without a need for its removal. For example, the cleaning process may be completed in between processing of batches of wafers/substrates.

The embodiments of the present disclosure can achieve several technical effects including in-situ EUV collector cleaning in a lithography apparatus without a need for costly replacements, swap-outs, or down-times for the apparatus by utilizing a cryogenic process and a magnetic trap. Additionally, cooling the collector may further enable source power scaling to prevent warping of the collector as both EUV and laser beam powers can be increased to meet requirements of a high volume manufacturing levels. Furthermore, the embodiments enjoy utility in various industrial applications as, for example, microprocessors, smart phones, mobile phones, cellular handsets, set-top boxes, DVD recorders and players, automotive navigation, printers and peripherals, networking and telecom equipment, gaming systems, digital cameras, or other devices utilizing logic or high-voltage technology nodes. The present disclosure therefore enjoys industrial applicability in any of various types of highly integrated semiconductor devices, including devices that use SRAM cells (e.g., liquid crystal display (LCD) drivers, digital processors, etc.), particularly for the 7 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a light source collector including a reflective surface;
applying a cooling agent to a surface of the collector for accelerating transformations of characteristics of contaminants on the reflective surface;
applying a purging agent to the reflective surface for dislodging the transformed contaminants; and
removing the dislodged contaminants to a collection pod remote from the reflective surface.

2. The method according to claim 1, further comprising:
coupling a cryogenic cooling chamber to the collector for the application of the cooling agent.

3. The method according to claim 1, further comprising:
coupling a purging chamber to an upper perimeter of the collector for the application of the purging agent; and
removing the dislodged contaminants to a center point at an upper surface of the collector for guiding the dislodged contaminants to the collection pod.

4. The method according to claim 3, further comprising:
applying a magnetic field to the center point at a lower surface of the collector for guiding the dislodged contaminants to the collection pod.

5. The method according to claim 1, wherein the transformed characteristics of the contaminants include a diamagnetic, semiconductor brittle state.

6. The method according to claim 1, wherein the contaminants include isotropic deposition and drip-on particles from a plasma material formed in generation of an extreme-ultraviolet beam.

7. The method according to claim 6, wherein the contaminants are from tin in a plasma state.

8. The method according to claim 1, further comprising:
cooling the surface of the collector to a temperature less than negative 20 degrees Celsius.

9. The method according to claim 1, wherein the light source collector is in a normal operating mode.

10. An apparatus comprising:
a light source collector including a reflective surface;
a cryogenic cooling chamber, including a cooling agent, coupled to the collector to accelerate transformations of characteristics of contaminants on the reflective surface;
a purging chamber, including a purging agent, coupled to an upper perimeter of the collector to apply the purging agent to dislodge the transformed contaminants; and
a collection pod remote from the reflective surface to collect the dislodged contaminants.

11. The apparatus according to claim 10, wherein the dislodged contaminants are guided to the collection pod through a channel at a center point of an upper surface of the collector.

12. The apparatus according to claim 11, further comprising:
a magnetic field applied to the center point of a lower surface of the collector to guide the dislodged contaminants to the collection pod.

13. The apparatus according to claim 10, wherein the transformed characteristics of the contaminants include a diamagnetic, semiconductor brittle state.

14. The apparatus according to claim 10, wherein the contaminants include isotropic deposition and drip-on particles from a plasma material formed in generation of an extreme-ultraviolet beam.

15. The apparatus according to claim 14, wherein the contaminants are from tin in a plasma state.

16. The apparatus according to claim 10, wherein the surface of the collector is cooled to a temperature less than negative 20 degrees Celsius.

17. The apparatus according to claim 10, wherein the light source collector is in a normal operating mode.

18. A method comprising:
providing a light source collector, in a normal operating mode, including a reflective surface;
coupling a cryogenic cooling chamber, including a cooling agent, to the collector;
applying the cooling agent to a surface of the collector, to reach a temperature less than negative 20 degrees Celsius, for accelerating transformation of contaminants on the reflective surface to a diamagnetic, semiconductor brittle state;
coupling a purging chamber, including a purging agent, to an upper perimeter of the collector;
applying the purging agent to the reflective surface for dislodging the transformed contaminants; and
removing the dislodged contaminants to a center point at an upper surface of the collector for guiding the dislodged contaminants to a collection pod remote from the reflective surface.

19. The method according to claim 18, further comprising:
applying a magnetic field to the center point at a lower surface of the collector for guiding the dislodged contaminants to the collection pod.

20. The method according to claim 18, wherein the contaminants include isotropic deposition and drip-on particles from tin in a plasma state formed in generation of an extreme-ultraviolet beam.
